(19) United States
(12) Patent Application Publication
(10) Pub. No.: US 2021/0333662 A1
(43) Pub. Date: Oct. 28, 2021

(54) BLACK PHOTORESIST, PREPARATION METHOD THEREOF, AND DISPLAY PANEL

(71) Applicant: TCL CHINA STAR OPTOELECTRONICS TECHNOLOGY CO., LTD., Shenzhen (CN)

(72) Inventor: Xiaoping YU, Shenzhen (CN)

(73) Assignee: TCL CHINA STAR OPTOELECTRONICS TECHNOLOGY CO., LTD., Shenzhen (CN)

(21) Appl. No.: 16/627,804

(22) PCT Filed: Dec. 26, 2019
(86) PCT No.: PCT/CN2019/128791

§ 371 Date: Dec. 31, 2019

(30) Foreign Application Priority Data
Dec. 13, 2019 (CN) 201911278938.9

(51) Int. Cl. G02F 1/1362; G03F 7/00; G03F 7/004

(52) U.S. Cl. CPC G02F 1/136209; G02F 1/136222; G03F 7/0045; G03F 7/0007

(57) ABSTRACT

The present invention discloses a black photoresist, a preparation method thereof, and a display panel, wherein the black photoresist includes photoresist reactive monomers and a dye, and the dye includes carbon black particles and an organic dye with a molecular weight of less than 1,000. In the above manner, the black photoresist described in the present invention reduces light scattering, thereby improving display contrast, which is beneficial to improving the display effect of the device.

### BACKGROUND OF INVENTION

### Field of Invention

The present invention relates to a field of display technology, in particular to a black photoresist, a preparation method thereof, and a display panel.

### Description of Prior Art

Contrast is one of important indicators to evaluate image quality performance of a liquid crystal display (LCD) screen. In a real use scene, due to the influence of ambient light, a reflectivity of a display panel will affect the contrast of the screen. As shown below, Lₒₙ, L_{off}, and R_{ambient} respectively indicate a bright state brightness of the display panel, a dark state brightness of the display panel, and an ambient brightness, and R_{L} represents a reflectance of the display panel. The contrast of the display panel can be increases by two aspects: 1) increasing the bright state brightness Lₒₙ of the display panel, and 2) reducing the reflectivity R_{L} of the display panel.

Contrast=(Lₒₙ+L_{ambient}*R_{L})/(L_{off}+L_{ambient}*R_{L})

In the prior art, a black matrix layer in the color filter substrate in the display panel has a strong light scattering property, causing part of light to be reflected out, and reducing the image quality of the display panel.

Therefore, the prior art needs to be further improved.

### SUMMARY OF INVENTION

The present invention provides a black photoresist, a method of preparing the same, and a display panel, which can solve the problem of poor display contrast caused by strong light scattering of a black matrix layer in the existing display panel.

In order to solve the above technical problem, a technical solution adopted by the present invention is to provide a black photoresist.

The black photoresist includes:

photoresist reactive monomers; and

a dye including carbon black particles and an organic dye having a molecular weight of less than 1000.

The organic dye includes a perylene dimer dye.

A perylene dimer in the perylene dimer dye has a structural formula as follows:

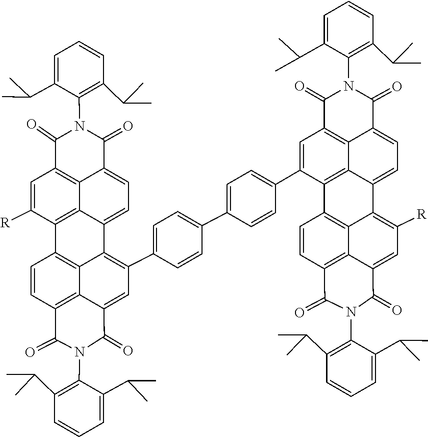

wherein R includes at least one of the following structural formulas:

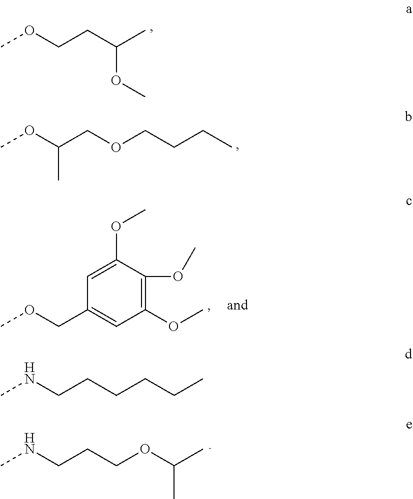

The R includes at least one group of a and d, a and e, b and d, c and d, and c and e.

Each of the carbon black particles has a size of less than 1 micrometer.

The dye is present in a mass fraction of greater than 20% in the black photoresist.

In order to the above technical problem, another technical solution adopted by the present invention is to provide a display panel, wherein the display panel includes:

an array substrate;

a color filter substrate corresponding to the array substrate;

a liquid crystal layer sandwiched between the array substrate and the color filter substrate; and

a light-shielding structure made of the black photoresist.

The light shielding structure includes a black matrix layer.

In order to solve the above technical problem, still another technical solution adopted by the present invention is to provide a method of preparing a black photoresist, wherein the method includes:

dispersing a dye to obtain a dye solution; and

mixing photoresist reactive monomers with the dye solution to obtain the black photoresist,

wherein the dye includes carbon black particles and an organic dye having a molecular weight of less than 1000.

The beneficial effects of the present application:

Different from the prior art, the present application introduces an organic dye with a small molecular weight to a black photoresist, and due to the small molecular weight of the organic dye, it has a poor ability to scatter light, and the reflected light is reduced, such that the display contrast of a display panel can be improved, thereby providing a better viewing experience.

### BRIEF DESCRIPTION OF DRAWINGS

FIG. 1 is a schematic structural diagram of a black photoresist according to an embodiment of the present application.

FIG. 2 is a schematic structural diagram of a display panel according to a first embodiment of the present application.

FIG. 3 is a schematic structural diagram of a display panel according to a second embodiment of the present application.

FIG. 4 is a schematic structural diagram of a display panel according to a third embodiment of the present application.

FIG. 5 is a schematic structural diagram of a display device according to an embodiment of the present application.

FIG. 6 is a schematic flowchart of a method of preparing a black photoresist according to an embodiment of the present application.

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

It should be noted that all directional indicators (such as up, down, left, right, front, back, etc.) in the embodiments of the present invention are only used to explain the relationship between components in a specific posture (as shown in the drawings). The relative positional relationship, movement situation, etc., if the specific posture changes, the directivity indication also changes accordingly.

In addition, the descriptions related to “first”, “second”, etc. in the present invention are only for descriptive purposes, and cannot be understood as indicating or implying their relative importance or implicitly indicating the number of technical features indicated. Therefore, the features defined as “first” and “second” may explicitly or implicitly include at least one of the features. In addition, the technical solutions between the various embodiments can be combined with each other, but must be based on those that can be realized by a person of ordinary skill in the art. When the combination of technical solutions conflicts or cannot be achieved, such a combination of technical solutions should be considered non-existent and not within the scope of protection claimed by the present invention.

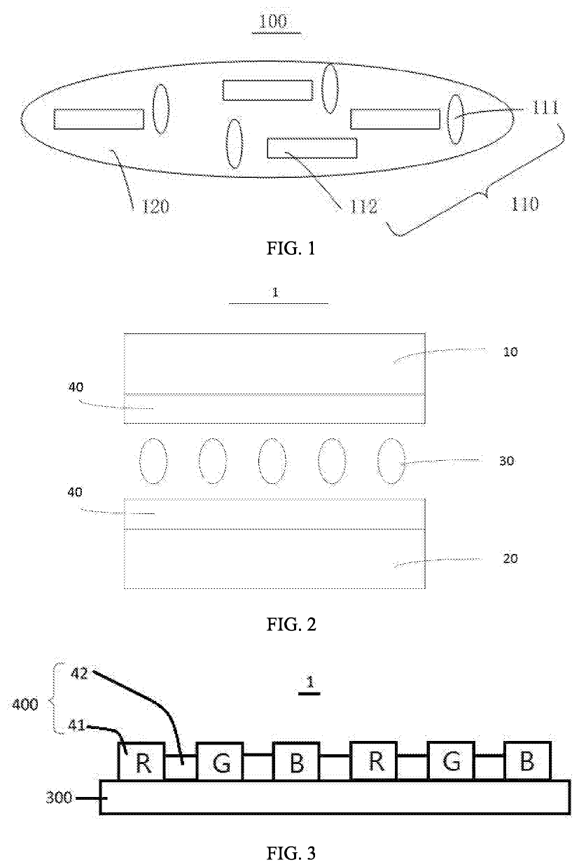

Refer to FIG. 1. FIG. 1 is a schematic structural diagram of a black photoresist according to an embodiment of the present application. The black photoresist includes: photoresist reaction monomers; and a dye including carbon black particles and an organic dye having a molecular weight of less than 1000.

In this embodiment, an organic dye with a small molecular weight is introduced to a black photoresist, and due to the small molecular weight of the organic dye, it has a poor ability to scatter light, and the reflected light is reduced, such that the display contrast of a display panel can be improved, thereby providing a better viewing experience.

Specifically, the photoresist reactive monomers are main components in the black photoresist, which are polymerized to obtain a photoresist. The dye enables the photoresist to have a corresponding color. In this embodiment, the dye is a black dye, specifically including the carbon black particles and the organic dye having a molecular weight of less than 1000. Performance of the photoresist is closely related to uniformity of its color. In order to fully mix the photoresist reactive monomers and the dye, fully stirring or adding a dispersant during the preparation process can be adopted to improve the mixing uniformity. Further, in order to obtain a better mixing effect, and sizes of the carbon black particles needs to be uniform, that is, a particle size distribution of the carbon black particles is relatively concentrated.

Specifically, sizes of the carbon black particles have a certain effect on the preparation process and performance of the black photoresist. The use of smaller particles having sizes of, for example, a few nanometers or less, not only causes a higher cost, but also generates dust in the production process, which endangers operator's health. However, if the sizes of the carbon black particles are too large, it is not conducive to their uniform dispersion in the black photoresist system. Therefore, the sizes of the carbon black particles are less than 1 micrometer, for example, 0.1 micrometer, 0.3 micrometer, 0.5 micrometer, 0.7 micrometer, 0.9 micrometer, or the like. In an embodiment, in order to prevent the sizes of the carbon black particles from impacting the mixing effect of the black photoresist, the sizes of the carbon black particles are 0.3 μm to 0.5 μm.

In this embodiment, the dye is present in a mass fraction of greater than 20%, such as 25%, 30%, 60%, 80%, 90%, or so on. The specific addition amount is related to the properties of the dye and the property requirements of the black photoresist, and is not specifically limited herein. Further, on the premise of ensuring the performance of the product, reducing the usage amount of the dye, especially an organic dye, as much as possible is not only conducive to simplifying the process of preparing the photoresist, but also reducing the production cost of the photoresist.

In this embodiment, the reactive monomers must have heat resistance to avoid damage to the structure due to high-temperature baking during the process of preparing the light-shielding layer, thereby impacting the use effect. For example, the reactive monomers may be polyimide reactive monomers. In order to simplify the process and obtain better results, the organic dye needs to have good solubility, heat resistance and absorbance properties in commonly used solvents (such as monomethyl ether propylene glycol acetate (PGMEA)). Correspondingly, the organic dye may be a perylene dimer dye or a mixture of the perylene dimer dye and carbon black, wherein the perylene dimer is excellent in heat resistance and can withstand a temperature reaching 320 degrees Celsius.

Specifically, the organic dye includes a perylene dimer dye having a structural formula as follows:

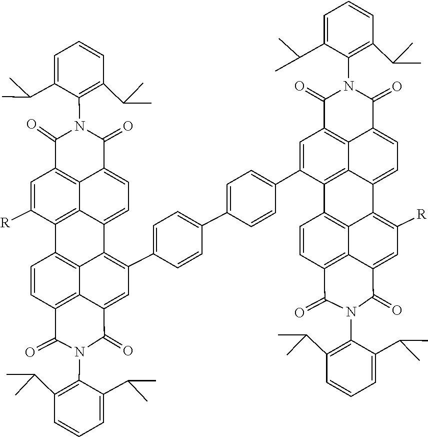

wherein R includes at least one of the following structural formulas:

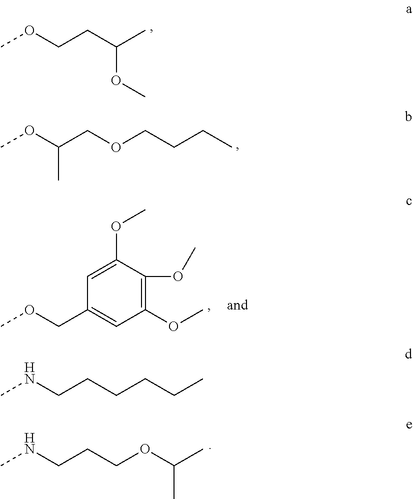

Furthermore, two R in the structural formula of the fluorene dimer may have the same structure or different structures. When the structures of the two R are different, each of them includes at least one group of a and d, a and e, b and d, c and d, and c and e, and any of the above groups can be used to further improve the light shielding effect of the black photoresist.

In order to solve the above technical problems, a technical solution adopted by the present invention is to provide a display panel. Please refer to FIG. 2, which is a schematic structural diagram of a display panel according to a first embodiment of the present invention. The display panel 1 includes:

an array substrate 10; a color filter substrate 20 disposed corresponding to the array substrate 10; a liquid crystal layer 30 sandwiched between the array substrate 10 and the color filter substrate 20; and a light-shielding structure 40 made of the black photoresist. Further, the light shielding structure 40 includes a black matrix layer disposed between color resist blocks of different colors to block light of a mixed color between the color resist blocks of different colors. Further, the light shielding structure 40 includes a black matrix layer.

Further, please refer to FIG. 3, which is a schematic structural diagram of a display panel according to a second embodiment of the present invention. The display panel 1 includes a first substrate 300 and a color resist layer 400 disposed on the first substrate 300. The color resist layer 400 includes color resist blocks 41 of different colors and a black matrix 42 disposed between the color resist blocks 41 of different colors. The black matrix 42 is configured to block light of a mixed color between the color resist blocks 41 of different colors. Specifically, the first substrate 300 may be an array substrate or a color filter substrate. For a COA panel, the black matrix is disposed on the array substrate 10. The color resist blocks 41 include a red color resist block, a green color resist block, and a blue color resist block, and of course, a white color resist block may also be introduced according to product requirements.

Of course, a first metal layer, a first insulating layer, a semiconductor layer, and a second metal layer are further disposed between the color resist layer 400 and the first substrate 300 sequentially. A reflection blocking layer is disposed on the metal layer close to a viewer to reduce the reflectance of the array substrate to ambient light. When the array substrate faces the viewer, and the first substrate 300 is an array substrate, the reflection blocking layer is provided between the first metal layer and the base substrate, and/or between the second metal layer and the semiconductor layer. When the color filter substrate faces the viewer, and the first substrate 300 is an array substrate, the reflection blocking layer is provided between the first metal layer and the first insulating layer, and/or between the second metal layer and the color resist layer.

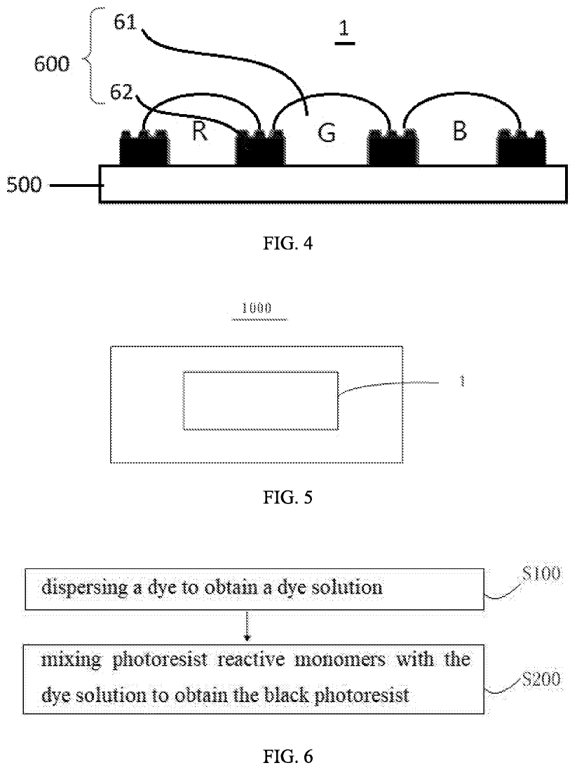

Further, referring to FIG. 4, FIG. 4 is a schematic structural diagram of a display panel according to a third embodiment of the present invention. The display panel 1 in this embodiment is formed by inkjet printing, and includes a first substrate 500 and a color resist layer 600 on the first substrate 500, and the color resist layer 600 includes a retaining wall 62 for blocking light of a mixed color between color resist blocks 61 of different colors.

The inkjet printed wall material (bank material) is made of the black photoresist described in the present application. When the retaining wall material is made by lithography, a specially designed gray scale photomask is used to make a front surface of the retaining wall material to show a regular uneven microstructure to change hydrophobicity of the retaining wall material. As a result, a side surface and a front surface of the retaining wall material exhibit different hydrophilic and hydrophobic characteristics, thereby ensuring that the inkjet droplets do not overflow.

In order to solve the above technical problems, another technical solution adopted by the present invention is to provide a display device.

Referring to FIG. 5, FIG. 5 is a schematic structural diagram of a display device according to an embodiment of the present application. The display device 1000 includes the display panel 1. The display device 1000 includes a fixed display device and a mobile display device. The fixed display device includes, but is not limited to, a television, a desktop display, etc., especially a fixed display device with a narrow bezel or no bezel. The mobile display device includes, but is not limited to, a mobile phone, a tablet computer, a smart watch, VR glasses, and the like.

In order to solve the above technical problems, yet another technical solution adopted by the present invention is to provide a method of preparing a black photoresist.

Referring to FIG. 6, FIG. 6 is a flowchart of a method of preparing a black photoresist according to an embodiment of the present application. The method includes the following steps:

S100. dispersing a dye to obtain a dye solution.

In the step S100, the dye for preparing the photoresist needs to be fully dissolved to avoid poor light shielding performance of the prepared photoresist due to uneven color. In this embodiment, the dye needs to be sufficiently dispersed, possibly by mechanically stirring, or introduction of a dispersant. Specifically, the stirring time and rotation speed can be set according to the amount and properties of the dye, and therefore are not specifically limited herein. The dispersant may be a resin-based dispersant, and further, the dispersant is an alkali-soluble dispersant.

S200. mixing photoresist reactive monomers with the dye solution to obtain the black photoresist, wherein the dye includes carbon black particles and an organic dye having a molecular weight of less than 1000.

In step S200, the photoresist reactive monomers are sufficiently mixed with the dye solution. In order to ensure the mixing effect, the dye may be mechanically stirred, or a dispersant may be added thereto. Specifically, the stirring time and rotation speed can be set according to the amount and properties of the dye, and therefore are not specifically limited herein. The dispersant may be a resin-based dispersant, and further, the dispersant is an alkali-soluble dispersant. Further, in order to avoid insufficient mixing of the dye and the photoresist reactive monomers, the sizes of the carbon black particles needs to be uniform, that is, the particle size distribution of the carbon black particles is relatively concentrated.

In this embodiment, since the dye includes an organic dye with a small molecular weight and thus has a poor ability to scatter light, a display panel prepared by using the photoresist has reduced light reflected from a light-shielding structure such as a black matrix, such that the display contrast of a display panel can be improved, thereby providing a better viewing experience.

Of course, the black photoresist further includes a photoinitiator, a solvent, an additive, and the like, wherein the photoinitiator is configured to initiate polymerization of the photoresist reactive monomers. Obviously, the type and amount of the photoinitiator are closely related to the type of the photoresist reactive monomers, and are not specifically limited herein. In addition, the black photoresist generally needs to be subjected to the stages of coating, pre-baking, exposure, development, and post-baking. According to different product requirements, the above-mentioned preparation process and specific operating parameters are different, and are not specifically limited herein.

The technical benefits and technical details of embodiments of the present application have been explained in detail in the foregoing, so they are not repeated herein for brevity.

In summary, the present application adds an organic dye with a small molecular weight to a black photoresist, and due to the small molecular weight of the organic dye, it has a poor ability to scatter light, and the reflected light is reduced, such that the display contrast of a display panel can be improved, thereby providing a better viewing experience.

The above is only an embodiment of the present invention, and thus does not limit the patent scope of the present invention. Any equivalent structure or equivalent process transformation made by using the description and drawings of the present invention, or directly or indirectly applied to other related technologies are all the same included in the patent protection scope of the present invention.

What is claimed is:

1. A black photoresist, comprising:
photoresist reactive monomers; and
a dye comprising carbon black particles and an organic dye having a molecular weight of less than 1000.

2. The black photoresist according to claim 1, wherein the organic dye comprises a perylene dimer dye.

3. The black photoresist according to claim 2, wherein a perylene dimer in the perylene dimer dye has a structural formula as follows: 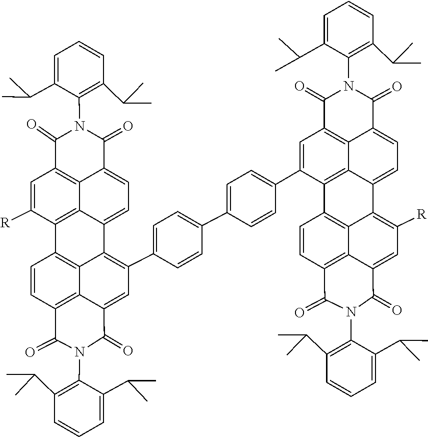
wherein R comprises at least one of the following structural formulas:

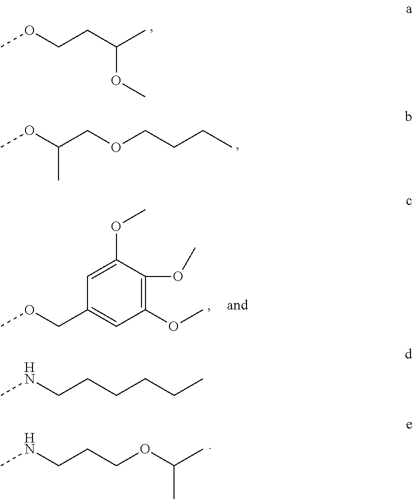

4. The black photoresist according to claim 3, wherein R comprises at least one group of a and d, a and e, b and d, c and d, and c and e.

5. The black photoresist according to claim 1, wherein each of the carbon black particles has a size of less than 1 micrometer.

6. The black photoresist according to claim 1, wherein the dye is present in a mass fraction of greater than 20% in the black photoresist.

7. A display panel, comprises:
an array substrate;
a color filter substrate corresponding to the array substrate;
a liquid crystal layer sandwiched between the array substrate and the color filter substrate; and
a light-shielding structure made of the black photoresist according to claim 1.

8. The display panel according to claim 7, wherein the light shielding structure comprises a black matrix layer.

9. A method of preparing a black photoresist, comprising:
dispersing a dye to obtain a dye solution; and
mixing photoresist reactive monomers with the dye solution to obtain the black photoresist,
wherein the dye comprises carbon black particles and an organic dye having a molecular weight of less than 1000.
